(19) United States
(12) Patent Application Publication
(10) Pub. No.: US 2026/0214877 A1
(43) Pub. Date: Jul. 23, 2026

(54) SRAM MEMORY ADOPTING CFET STRUCTURES

(71) Applicant: Taiwan Semiconductor Manufacturing Co., Ltd., Hsinchu (TW)

(72) Inventors: Cheng-Yin Wang, Taipei City (TW); Jui-Chien Huang, Hsinchu (TW); Ting-Yun Wu, Taipei City (TW); Meng-Yu Lin, New Taipei City (TW); Lu Yang, Hsinchu (TW); Szuya Liao, Zhubei (TW)

(21) Appl. No.: 19/203,538

(22) Filed: May 9, 2025

Related U.S. Application Data
(60) Provisional application No. 63/748,588, filed on Jan. 23, 2025.

(51) Int. Cl. H10B 10/00; G11C 11/412

(52) U.S. Cl. CPC H10B 10/12; G11C 11/412

(57) ABSTRACT

A device includes a static random-access memory (SRAM) cell that further includes a first complementary field-effect transistor and a second complementary field-effect transistor electrically connecting to the first complementary field-effect transistor. The first complementary field-effect transistor includes a first pull-up transistor, and a first pull-down transistor electrically connected to the first pull-up transistor at a first storage node. The second complementary field-effect transistor includes a second pull-up transistor, and a second pull-down transistor electrically connected to the second pull-up transistor at a second storage node. The SRAM cell further includes a pass-gate transistor overlying the first complementary field-effect transistor and the second complementary field-effect transistor.

### PRIORITY CLAIM AND CROSS-REFERENCE

This application claims the benefit of the following provisionally filed U.S. Patent application: Application No. 63/748,588, filed on Jan. 23, 2025, and entitled “CFET MEMORY STRUCTURE,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic circuit diagram of a 6-T SRAM cell in accordance with some embodiments.

FIG. 2 illustrates a perspective view of a CFET structure comprising a pull-up transistor and a pull-down transistor in accordance with some embodiments.

FIG. 3A illustrates a top view (and a layout) of an example SRAM cell and the transistors therein in accordance with some embodiments.

FIG. 3B illustrates the cross-sections for obtaining cross-sectional views of a SRAM cell in accordance with some embodiments.

FIGS. 4A and 4B illustrate cross-sectional views of the SRAM cell in accordance with some embodiments.

FIG. 5 illustrates a top view of an upper part of the SRAM cell in accordance with some embodiments.

FIG. 6 illustrates a bottom view of a lower part of the SRAM cell in accordance with some embodiments.

FIGS. 7 and 8 illustrate cross-sectional views obtained along lengthwise directions of CFETs of the SRAM cell in accordance with some embodiments.

FIGS. 9A and 9B illustrate cross-sectional views obtained along lengthwise directions of pass-gate transistors in SRAM cells in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Static Random-Access Memory (SRAM) cell, which may be a six-transistor (6T) transistor, and the respective layouts are illustrated. In accordance with some embodiments of the present disclosure, the 6T SRAM cell is designed to occupy the foot print of two transistor by adopting two Complementary Field-Effect Transistors (CFETs), so that the size of the SRAM cell is minimized. The SRAM cell comprises a first CFET and a second CFET. The first CFET comprises a first pull-up transistor and a first pull-down transistor. The second CFET comprises a second pull-up transistor and a second pull-down transistor. Two pass-gate transistors are formed, with a first pass-gate transistor overlapping the two CFETs, and a second pass-gate transistor overlapped by the two CFETs. Accordingly, the pass-gate transistors do not occupy extra chip area more than the chip area occupied by the two CFETs, and the total footprint of the SRAM cell is equal to the footprint of two transistors.

While a 6T SRAM cell is discussed as an example, the SRAM cell may be a 8T SRAM cell, a 10T SRAM cell, a 12T SRAM cell, or the like. Embodiments discussed herein are to provide examples to enable making or using the subject matter of this disclosure, and a person having ordinary skill in the art will readily understand modifications that can be made while remaining within contemplated scopes of different embodiments.

Throughout the various views and illustrative embodiments, like reference numbers are used to designate like elements. Although method embodiments may be discussed as being performed in a particular order, other method embodiments may be performed in any logical order.

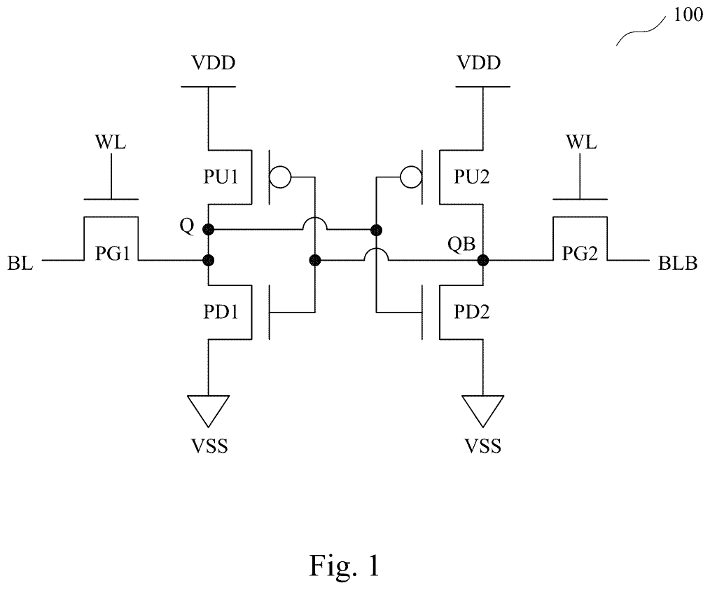

FIG. 1 illustrates a circuit diagram of SRAM cell 100 in accordance with some embodiments. SRAM cell 100 includes pull-up transistors PU1 and PU2, which are p-type transistors (PFETs). SRAM cell 100 further includes pull-down transistors PD1 and PD2 and pass-gate transistors PG1 and PG2, which may be n-type transistors. The gates of pass-gate transistors PG1 and PG2 are connected to and controlled by word-line WL that determines whether SRAM cell 100 is selected or not.

Throughout the description, the terms “Field-Effect Transistor (FET)” and “transistor” are used interchangeably. Also, pull-up transistors PU1 and PU2 are individually and collectively referred to as pull-up transistors PU, pull-down transistors PD1 and PD2 are individually and collectively referred to as pull-down transistors PD, and pass-gate transistors PG1 and PG2 are individually and collectively referred to as pass-gate transistors PG.

A latch formed of pull-up transistors PU1 and PU2 and pull-down transistors PD1 and PD2 is capable of storing a bit, wherein the complementary values of the bit are stored in storage nodes Q and QB. The stored bit can be written into or read from SRAM cell 100 through complementary bit lines including bit-line (BL) and bit-line bar (BLB).

SRAM cell 100 is powered through a positive power supply node VDD that has a positive power supply voltage (also referred to as Vdd). SRAM cell 100 is also connected to power supply voltage VSS (also referred as Vss), which may be an electrical ground. Transistors PU1 and PD1 form a first inverter. Transistors PU2 and PD2 form a second inverter. The input of the first inverter is connected to transistor PG1 and the output of the second inverter. The output of the first inverter is connected to transistor PG2 and the input of the second inverter.

The sources of pull-up transistors PU1 and PU2 are connected to the VDD node, which is further connected to power supply voltage (and line) VDD. The sources pull-down transistors PD1 and PD2 are connected to the VSS node, which is further connected to power supply voltage/line VSS. The gates of transistors PU1 and PD1 are connected to the drains of transistors PU2 and PD2, which form a connection node that is referred to as the storage node QB. The gates of transistors PU2 and PD2 are connected to the drains of transistors PU1 and PD1, which connection node is referred to as the storage node Q. A source/drain region of pass-gate transistor PG1 is connected to bit line BL at a BL node. A source/drain region of pass-gate transistor PG2 is connected to bit line BLB at a BLB node.

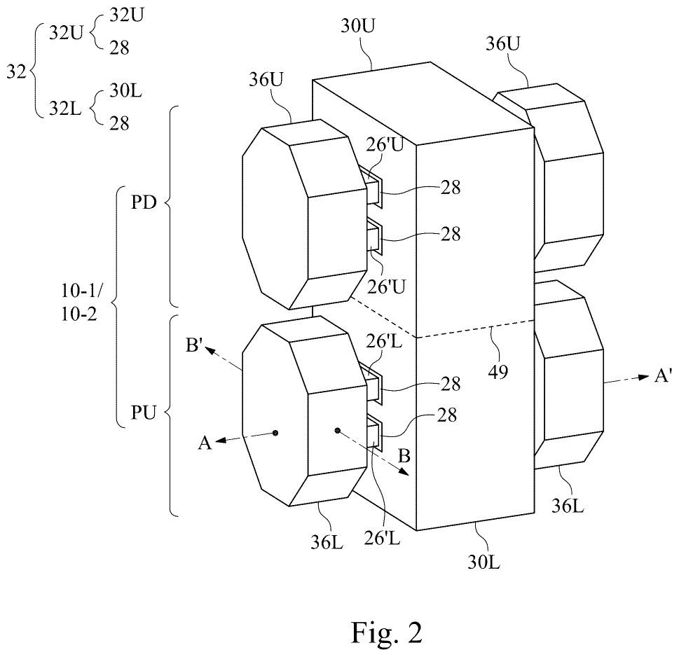

In accordance with some embodiments, the p-type transistors and the n-type transistors of SRAM cell 100 may be implemented using CFETs, which may have the structure as shown in FIG. 2. It is appreciated that CFETs may have p-type transistors and n-type transistors in pairs. The SRAM cell 100, however, may have the total number of p-type transistors different from the total number of n-type transistors. For example, the example SRAM cell 100 as shown in FIG. 1 may include four p-type transistors and two n-type transistors, and hence the p-type transistors and n-type transistors are not in pairs. Due to the structure of CFETs, each of the un-paired transistors may occupy the footprint of a CFET, and the chip area usage is a half of a CFET. The embodiments of the present disclosure provide the structures for implementing the un-paired PFETs (or n-type transistors when pass-gate transistors are p-type transistors) for forming pass-gate transistors.

FIG. 2 illustrates an example of CFET 10 (including FETs (transistors) PU and PD) in accordance with some embodiments. The CFETs 10 may be CFET 10-1 or CFET 10-2. The p-type transistor PU1 and n-type transistor PD1 in FIG. 1 may be formed as a first CFET having the structure as shown in FIG. 2. The p-type transistor PU2 and n-type transistor PD2 may also be formed as a second CFET, also having the structure as shown in FIG. 2. FIG. 2 is a three-dimensional view, wherein some features of the CFETs are omitted for illustration clarity.

In accordance with some embodiments, as shown in FIG. 2, p-type transistors are formed as the lower transistors of the CFETs, and n-type transistors are formed as the upper transistors of the CFETs. In accordance with alternative embodiments, n-type transistors may be formed as the lower transistors of the CFETs, and p-type transistors may be formed as the upper transistors of the CFETs. Throughout the description and subsequent figures of the present disclosure, it is assumed that the lower transistors are p-type transistors (pull-down transistors), and the upper transistors are n-type transistors (pull-up transistors).

In accordance with some embodiments, the pull-down transistors PD1 and PD2 and pull-up transistors PU1 and PU2 are formed as gate-all-around transistors. In accordance with other embodiments, the pull-down transistors PD1 and PD2 and pull-up transistors PU1 and PU2 may be formed as other types of transistors such as Fin Field-Effect Transistors (FinFETs), planar transistors, or the combinations thereof.

In the example embodiments as shown in FIG. 2, the pull-up transistor PU and the pull-down transistor PD are GAA transistors, which are also referred to as nanostructure transistors. The GAA transistors PU and PD include semiconductor nanostructures 26′ (including lower semiconductor nanostructures 26′L and upper semiconductor nanostructures 26′U), where the semiconductor nanostructures 26′ act as the channel regions for the GAA transistors. The lower semiconductor nanostructures 26′L are for the lower GAA transistor PU, and the upper semiconductor nanostructures 26′U are for the upper GAA transistor PD.

Gate dielectrics 28 encircle the respective semiconductor nanostructures 26′. Gate electrodes 30 (including a lower gate electrode 30L and an upper gate electrode 30U) are over the gate dielectrics 28. Gate dielectrics 28 and lower gate electrode 30L are collectively referred to as gate stacks 32L, and gate dielectrics 28 and upper gate electrode 30U are collectively referred to as gate stacks 32U. Gate stacks 32U and 32L are individually and collectively referred to as gate stacks 32.

Lower gate electrode 30L and upper gate electrode 30U are electrically interconnected, and may be parts of a same continuous and homogenous gate electrode. Alternatively, Lower gate electrode 30L and upper gate electrode 30U may be formed of different materials, which are in contact with each other. Lower gate electrode 30L and upper gate electrode 30U are individually and collectively referred to as gate electrode(s) 30.

Source/drain regions 36 (including lower source/drain regions 36L and upper source/drain regions 36U) are formed on opposing sides of the gate dielectrics 28 and the respective gate electrodes 30. Source/drain region(s) may refer to a source or a drain, individually or collectively dependent upon the context. The source/drain region may refer to a source or a drain, individually or collectively dependent upon the context. Isolation features (not shown) may be formed to separate desired ones of the source/drain regions 36 and/or desired ones of the gate electrodes 30.

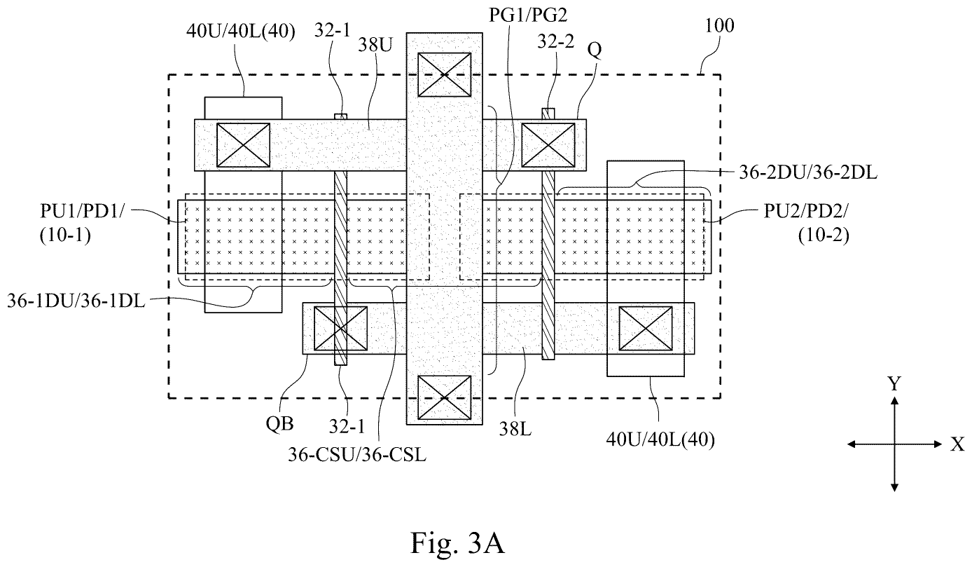

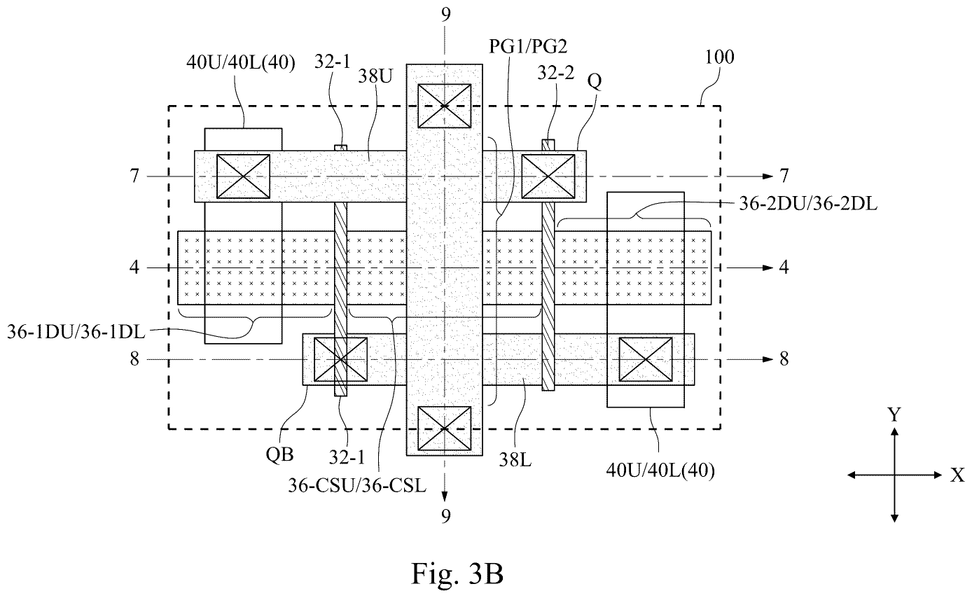

FIGS. 3A and 3B illustrate the top views (which are also the same as layouts) of SRAM cell 100 in accordance with some embodiments. The SRAM cell 100 discussed throughout the description may be formed on physical semiconductor wafers. FIGS. 3A and 3B illustrate a same structure. To make the figures clear to view, markings of reference numbers are separated into FIGS. 3A and 3B. For example, FIG. 3A illustrates the positions of transistors and the respective gate stacks and source/drain regions. FIG. 3B illustrates some marked cross-sections, from which the cross-sectional views in subsequent figures are obtained. Some of markings in one of FIGS. 3A and 3B may not be shown in the other, and the markings in FIGS. 3A and 3B may be combined for understanding the structure of SRAM cell 100.

As shown in FIG. 3A, SRAM cell 100 includes CFET 10-1 forming a first inverter, and CFET 10-2 forming a second inverter. The CFET 10-1 comprises pull-up transistor PU1 and pull-down transistor PD1. The channel length direction (source-to-drain direction) of pull-up transistor PU1 and pull-down transistor PD1 may be in the X-direction. Pull-up transistor PU1 and pull-down transistor PD1 share gate stack 32-1.

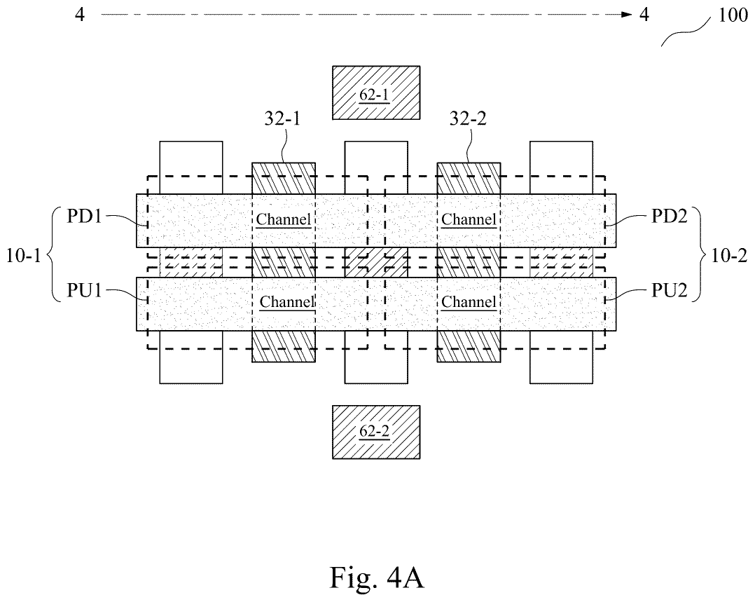

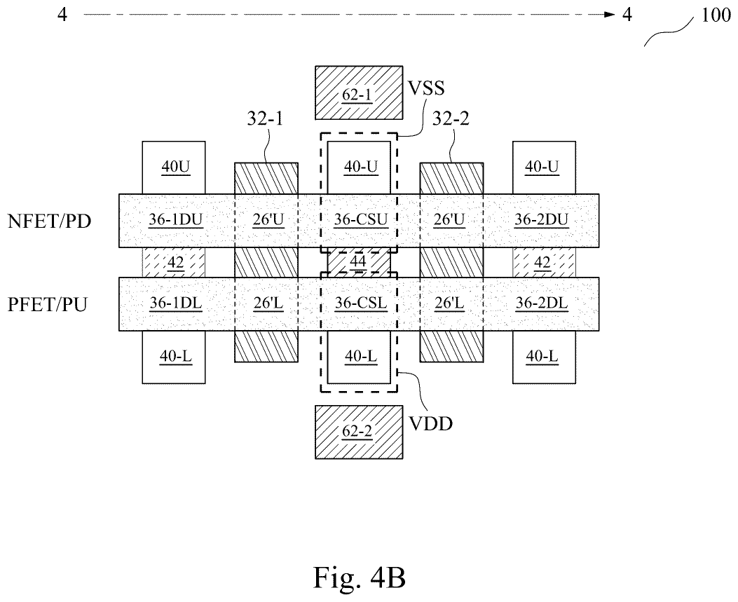

On the right side of gate stack 32-1, common source regions 36-CDU/36-CDL are located, wherein the common source regions 36-CDU/36-CDL (which correspond to regions 36U/36L in FIG. 2) include the upper common source region 36-CSU and lower common source region 36-CSL. Throughout the description, the notation “36-CDU/36-CDL” indicates both of features 36-CDU and 36-CDL. The positions of upper common source region 36-CSU and lower common source region 36-CSL may be viewed in FIG. 4B.

Referring back to FIG. 3A, on the left side of gate stack 32-1, drain regions 36-1DU/36-1DL (which also correspond to regions 36U/36L in FIG. 2) are located, wherein the drain regions 36-1DU/36-1DL include upper drain region 36-1DU and lower drain region 36-1DL. Upper drain region 36-1DU is electrically connected to lower drain region 36-1DL through a contact plug 42 (FIG. 4B) formed therebetween. The positions of the upper drain region 36-1DU and lower drain region 36-1DL may also be viewed in FIG. 4B.

The CFET 20-2 comprises pull-up transistor PU2 and pull-down transistor PD2. The channel length direction (source-to-drain direction) of pull-up transistor PU2 and pull-down transistor PD2 may be in the X-direction. Pull-up transistor PU2 and pull-down transistor PD2 share gate stack 32-2.

On the left side of gate stack 32-2, common source regions 36-CDU/36-CDL are located. Common source region 36-CDU is shared by upper transistors (pull-down transistors) PD1 and PD2. Common source region 36-CDL is shared by lower transistors (pull-up transistors) PU1 and PU2. The positions of upper common source region 36-CSU and lower common source region 36-CSL may be viewed in FIG. 4B.

On the right side of gate stack 32-2, drain regions 36-2DU/36-2DL (which correspond to regions 36U/36L in FIG. 2) are located, wherein the drain regions 36-2DU/36-2DL include upper drain region 36-2DU and lower drain region 36-2DL. Upper drain region 36-2DU is electrically connected to lower drain region 36-2DL through a contact plug 42 (FIG. 4B) formed therebetween. The positions of the upper drain region 36-2DU and lower drain region 36-2DL may also be viewed in FIG. 4B.

Further referring to FIG. 3A, pass-gate transistors PG1 and PG2 are formed. In accordance with some embodiments, pass-gate transistors PG1 and PG2 may occupy a same footprint. For example, both of pass-gate transistors PG1 and PG2 may be formed at the center of SRAM cell 100 when viewed in the top view. The lengthwise directions of pass-gate transistors PG1 and PG2 may be in the Y-direction in the illustrated embodiments, or in the X-direction in other embodiments. In accordance with alternative embodiments, pass-gate transistors PG1 and PG2 may occupy different footprints. For example, pass-gate transistors PG1 and PG2 may be formed on opposing sides (+X side and −X side) of CFETs 10-1 and 10-2.

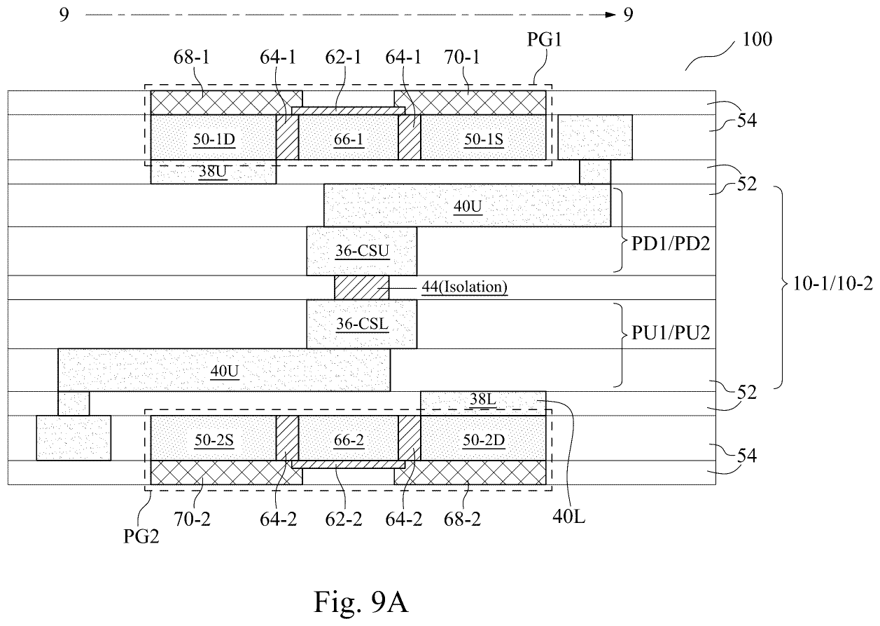

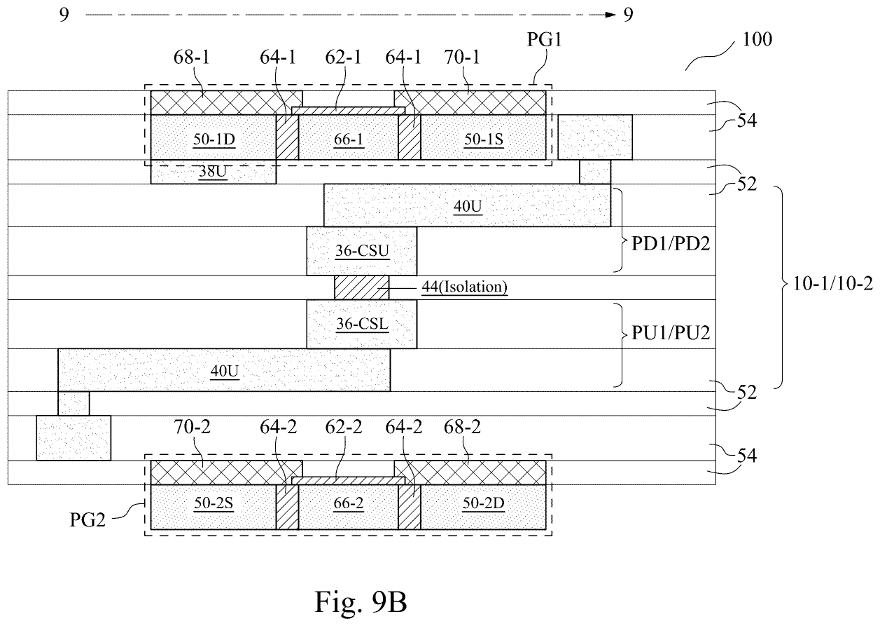

In accordance with some embodiments, as may be realized from FIG. 9A, pass-gate transistor PG1 may be on the front side of, and may overlap the CFETs 10-1 and 10-2. Pass-gate transistor PG2 may be on the back side of, and may be overlapped by, the CFETs 10-1 and 10-2. Pass-gate transistors PG1 and PG2 may also occupy the same footprint of CFETs 10-1 and 10-2, and hence pass-gate transistors PG1 and PG2 do not occupy extra chip area in addition to the chip area occupied by CFETs 10-1 and 10-2. This effectively reduces the footprint of the SRAM cell 100 to the same footprint of CFETs 10-1 and 10-2.

In accordance with alternative embodiments, both of pass-gate transistors PG1 and PG2 may be formed on the front side of CFETs 10-1 and 10-2, or both of pass-gate transistors PG1 and PG2 may be formed on the backside of CFETs 10-1 and 10-2.

In accordance with some embodiments, pass-gate transistors PG1 and PG2 are thin-film transistors, which may adopt InGaZnO (IGZO) as the material of channel regions. The pass-gate transistors PG1 and PG2 may be formed in the metal layers (for example, in dielectric layers such as low-k dielectric layers), and may be formed over CFETs 10-1 and 10-2 or under CFETs 10-1 and 10-2. The detailed structure of pass-gate transistors PG1 and PG2 may be discussed referring to FIG. 9A as an example.

Source/drain contact plugs 40, which include source/drain contact plugs 40U and 40L, are also formed. One of the source/drain contact plugs 40U, which is on the left side of the illustrate SRAM cell 100, electrically connects the gate stack 32-2 to the drain regions 36-1DU and 36-1DL to form storage node Q (also refer to FIG. 1). The electrical connection for connecting gate stack 32-2 to the drain regions 36-1DU and 36-1DL include body contact 38U, which may be connected to the gate stack 32-2 and the drain regions 36-1DU through vias, which are illustrated and not specifically marked. Alternatively, body contact 38U may be in physical contact with either one or both of gate stack 32-2 and drain regions 36-1DU.

Another one of the source/drain contact plugs 40U, which is on the right part of the illustrate SRAM cell 100, electrically connects the gate stack 32-1 to the drain regions 36-2DU and 36-2DL to form storage node QB.

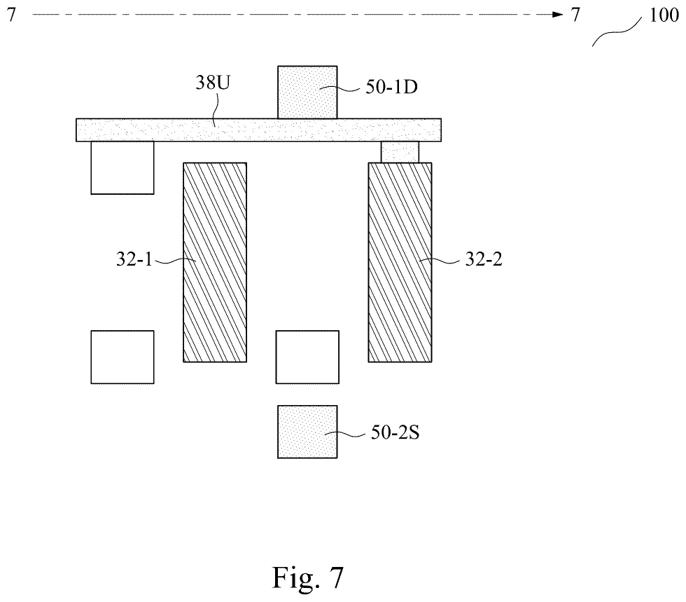

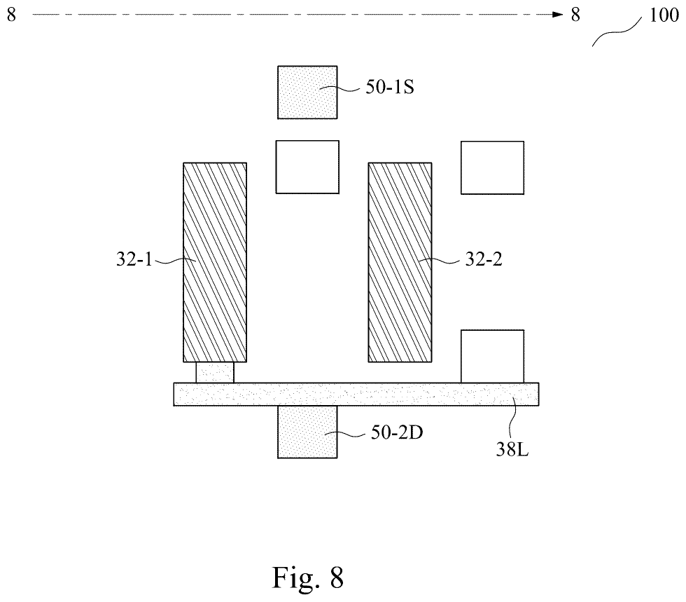

In FIG. 3B, four cross-sections 4-4, 7-7, 8-8, and 9-9 are illustrated. FIGS. 4A and 4B illustrate the structure in the cross-section 4-4 in FIG. 3B. FIG. 7 illustrates the structure in the cross-section 7-7 in FIG. 3B. FIG. 8 illustrates the structure in the cross-section 8-8 in FIG. 3B. FIG. 9A illustrates the structure in the cross-section 9-9 in FIG. 3B. Also, each cross-section is represented using an arrow, and the direction of the arrows are also shown in the respective cross-sectional views.

FIGS. 4A and 4B illustrate the cross-sectional view of the cross-section 4-4 in FIG. 3B. FIGS. 4A and 4B illustrate a same structure. To make the figures clear to see, markings are separated into FIGS. 4A and 4B. For example, FIG. 4A illustrates the positions of CFETs, transistors, and the respective gate stacks and source/drain regions. FIG. 4B illustrates the components of the transistors and their connecting or isolation features. Some of markings such in one of FIGS. 4A and 4B may not be shown in the other, and the markings in FIGS. 4A and 4B may be combined for understanding the structure of SRAM cell 100.

The cross-section 4-4 in FIG. 3B cuts through the CFETs 10-1 and 10-2 (FIG. 4A), the corresponding pull-down transistors PD1 and PD2, and the pull-up transistors PU1 and PU2. The regions of the transistors are roughly marked in FIG. 4A. Gate stacks 32-1 and 32-2 extend from a level over the channel region (marked as “Channel”) of the pull-down transistors PD1 and PD2 to a level below the channel regions of the pull-up transistors PU1 and PU2. Gate stacks 32-1 and 32-2 form pull-down transistors PD1 and PD2 and pull-up transistors PU1 and PU2 in combination with the channel regions and source/drain regions, which are marked in FIG. 4B.

In FIG. 4B, pull-down transistor PD1 (refer to FIG. 4A) includes gate stack 32-1, common source region 36-CSU, and drain region 36-1DU. Pull-up transistor PU1 (refer to FIG. 4A) includes gate stack 32-1, common source region 36-CSL, and drain region 36-1DL. Drain region 36-1DU is electrically connected to the drain region 36-1DL through conductive feature 42, which may be a contact plug.

Pull-down transistor PD2 (FIG. 4A) includes gate stack 32-2, common source region 36-CSU, and drain region 36-2DU. Pull-up transistor PU2 (FIG. 4A) includes gate stack 32-2, common source region 36-CSL, and drain region 36-2DL. Drain region 36-2DU is electrically connected to the drain region 36-2DL through conductive feature 42, which may be a contact plug.

Common source region 36-CSU is electrically connected to an overlying source/drain contact plug 40-U, and is electrically connected to VSS. Common drain region 36-CSL is electrically connected to an underlying source/drain contact plug 40-L, and is electrically connected to VDD. Common source region 36-CSU is electrically insulated from common drain region 36-CSL by dielectric isolation region 44, so that power nodes VDD and VSS are not electrically shorted.

The cross-section 4-4 may also passes the gates 66-1 and 62-2 (also refer to FIG. 9A) of pass-gate transistors PG1 and PG2.

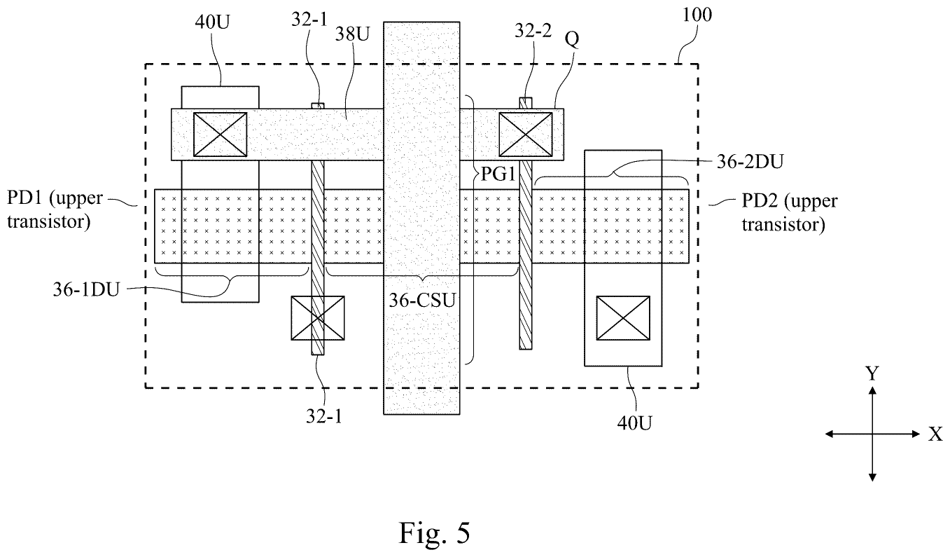

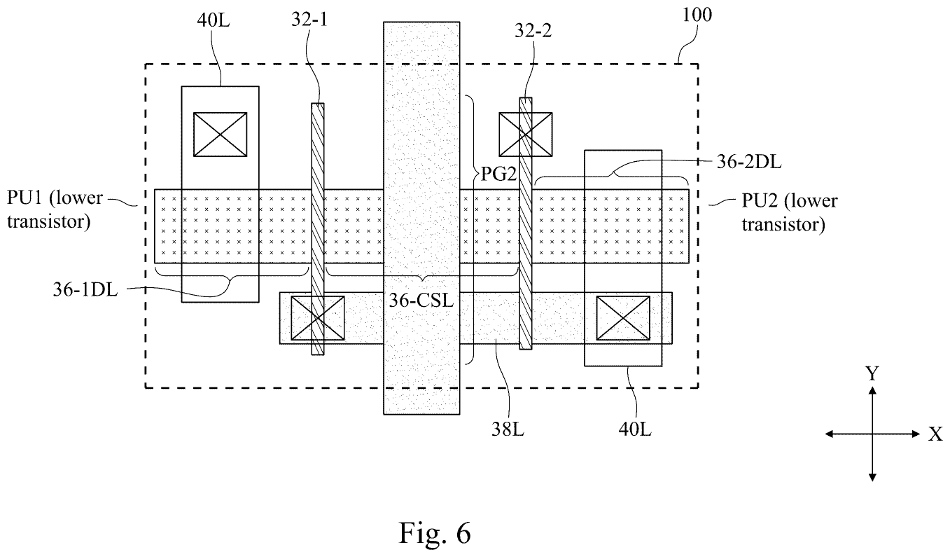

It is appreciated that in FIGS. 3A and 3B, the upper components of SRAM cell 100 including upper transistors (such as pull-down transistors PD1 and PD2 and pass-gate transistor PG1) are illustrated in the same regions as the lower components of SRAM cell 100 including lower transistors (such as pull-up transistors PU1 and PU2 and pass-gate transistor PG2). To help the understanding as what features are upper features and what features are lower features, the upper components and lower components are separated, and are illustrated in FIGS. 5 and 6, respectively.

FIG. 5 illustrates a top view of the upper part of SRAM cell 100 in accordance with some embodiments. As shown in FIG. 2, assuming level 49 is the level separating upper transistors from the respective lower transistors, FIG. 5 illustrates the portions of the features over level 49, and thus is considered as illustrating the front-side features of the SRAM cell 100.

As shown in FIG. 5, pull-down transistors PD1 and PD2 are formed on the left side and the right side, respectively, of SRAM cell 100, and have common source region 36-CSU, which is electrically connected to VSS (refer to FIG. 4B). The lengthwise directions of pull-down transistors PD1 and PD2 are in the X-direction. Pass-gate transistor PG1 is formed over pull-down transistors PD1 and PD2, and has lengthwise direction in the Y-direction. The upper parts of gate stacks 32-1 and 32-2 (also refer to gate stack 32 in FIG. 1) is also over the level 49 (FIG. 2). Gate stack 32-2 is electrically connected to the drain region 36-1DU through body contact plug 38U, and form storage node Q. On the right side of gate stack 32-2, another contact plug 40U is formed.

FIG. 6 illustrates a bottom view of the lower part of SRAM cell 100 in accordance with some embodiments. FIG. 6 illustrates the portions of the features under level 49 in FIG. 2, and thus is considered as illustrating the backside features of the SRAM cell 100.

As shown in FIG. 6, pull-up transistors PU1 and PU2 are formed on the left side and the right side, respectively, of SRAM cell 100, and have common source region 36-CSL, which is electrically connected to VDD (refer to FIG. 4B). The lengthwise directions of pull-up transistors PU1 and PU2 are in the X-direction. Pass-gate transistor PG2 is formed under pull-up transistors PU1 and PU2, and has lengthwise direction in the Y-direction. The lower parts of gate stacks 32-1 and 32-2 (also refer to gate stack 32 in FIG. 1) is also lower than the level 49 (FIG. 2). Gate stack 32-1 is electrically connected to the drain region 36-2DL through body contact plug 38L, and form storage node QB. On the left side of gate stack 32-1, another contact plug 40L is formed.

FIG. 7 illustrates a cross-sectional view of SRAM cell 100. The cross-sectional view is obtained from cross-section 7-7 in FIG. 3B. The cross-section passes through the drain region 50-1D of pass-gate transistor PG1 and the source region 50-2S of pass-gate transistor PG2. It is appreciated that the sizes of the source/drain regions of the pass-gate transistors PG1 and PG2 may be longer or shorter than illustrated. In accordance with some embodiments, body contact 38U is underlying and in physical contact with (and is electrically connected to) the drain region 50-1D. In accordance with alternatively embodiments, body contact 38U (also referred to as butted contact) is underlying and is electrically connected to the drain region 50-1D through a conductive via (not shown) in between. Gate stacks 32-1 and 32-2 are also in the illustrated cross-section.

FIG. 8 illustrates a cross-sectional view of SRAM cell 100. The cross-sectional view is obtained from cross-section 8-8 in FIG. 3B. The cross-section passes through the source region 50-1S of pass-gate transistor PG1 and the drain region 50-2D of pass-gate transistor PG2. It is appreciated that the sizes of the source/drain regions of the pass-gate transistors PG1 and PG2 may be longer or shorter than illustrated. In accordance with some embodiments, body contact 38L is overlying and in physical contact with (and is electrically connected to) the drain region 50-2D. In accordance with alternatively embodiments, body contact 38L is underlying and is electrically connected to the drain region 50-2D through a conductive via (not shown) in between. Gate stacks 32-1 and 32-2 are also in the illustrated cross-section.

FIG. 9A illustrates a cross-sectional view of SRAM cell 100. The cross-sectional view is obtained from cross-section 9-9 in FIG. 3B, which cross-section 9 -9 is in the Y-direction in FIG. 3B. FIG. 9A illustrates a cross-sectional view of pass-gate transistors PG1 and PG2 in accordance with some embodiments.

In accordance with some embodiments, pass-gate transistor PG1 is formed on the front side of, and is over CFETs 10-1 and 10-2. Furthermore, pass-gate transistor PG1 occupies the same footprint (chip area when viewed from top) as CFETs 10-1 and 10-2. In accordance with some embodiments, pass-gate transistor PG1 is formed over the source/drain contact plug 40U, which is formed in a dielectric layer 52. Dielectric layers 52 may be an inter-layer dielectric (ILD) in accordance with some embodiments, and may be formed of or comprise silicon oxide, phospho-silicate glass (PSG), borosilicate glass (BSG), boron-doped phospho-silicate glass (BPSG), fluorine-doped silicate glass (FSG), or the like.

Pass-gate transistor PG1 is formed in dielectric layers 54, which may be Inter-Metal Dielectric (IMD) layers. dielectric layers 54 may be formed of a low-k dielectric material having a dielectric constant (k-value) lower than about 3.8, and may be formed of or comprises a carbon-and-silicon containing dielectric material such as SiOCN.

FIG. 9A also illustrates an example structure of pass-gate transistors PG1 and PG2 in accordance with some embodiments. It is appreciated that pass-gate transistors PG1 and PG2 may have other structures other than illustrated, which structures are also in the scope of the present disclosure. The components in the pass-gate transistors PG1 and PG2 may be identified with the same reference numerals, with the components of pass-gate transistor PG1 having sign “−1” following the reference numbers, and the components of pass-gate transistor PG2 having sign “−2” following the reference numbers. Accordingly, the structure of pass-gate transistor PG1 is discussed as an example, while the structure of pass-gate transistor PG1 may be the same as (or may be different from) that of pass-gate transistor PG2.

In accordance with some embodiments, pass-gate transistor PG1 includes channel layer 62-1. Gate 66-1 is overlapped by channel layer 62-1. Gate spacers 64-1 are formed on opposing sides of the gate 66-1. Source region 50-1S and drain region 50-1D are on opposing sides of gate 66-1, and are spaced apart from gate 66-1 by dielectric gate spacers 64-1.

In accordance with some embodiments, the channel layer 62-1 is for forming an n-type transistor, which is turned on when a positive bias voltage is applied on gate 66-1 (relative to the voltage on the respective source region). In accordance with some embodiments when the resulting transistor is an n-type transistor, channel layer 62-1 may be formed of or comprise Indium Gallium Zinc Oxide (IGZO), Indium Tin Oxide (ITO), Indium Oxide (InO), Indium Zinc Oxide (IZO), Indium Tungsten Oxide (IWO), or the like, or combinations thereof,

In accordance with alternative embodiments, the channel layer 62-1 is for forming a p-type transistor, which is turned on when a negative bias voltage is applied on the gate (relative to the voltage on the respective source region). The respective channel layer 62-1 may also include an oxide such as NiO, CuO, Cr₂O₃, Co₃O₄, Mn₃O₄, or the like.

In accordance with some embodiments, source/drain regions 50 (including source region 50-1S and drain region 50-1D) may be in physical contact with channel layer 62-1.

In accordance with some embodiments, source/drain regions 50 are formed of or comprise Ti, TiN, W, Al, Mo, Ni, Cu, or the like, or alloys thereof. Vias 68-1 and 70-1 are electrically connected to source region 50-1S and 50-1D, respectively. Vias 68-1 and 70-1 may be formed of or comprise metals such as copper, tungsten, cobalt, aluminum, or the like. Via 70-1 is electrically connected to bit-line BL.

In accordance with some embodiments, pass-gate transistor PG2 may include channel layer 62-2, which may comprise InGaZnO (IGZO), which is a semiconductor. In accordance with some embodiments, source region 50-2S and drain region 50-2D are in contact with channel layer 62-2, and are spaced apart from the gate 66-2 by dielectric spacers 64-2. Vias 68-2 and 70-2 are electrically connected to source region 50-2S and 50-2D, respectively. Via 70-2 is electrically connected to bit-line BLB.

In accordance with some embodiments, pass-gate transistor PG2 has a same structure as pass-gate transistor PG1. In accordance with alternative embodiments, pass-gate transistor PG2 has a different structure than pass-gate transistor PG1. For example, pass-gate transistor PG2 may have the gate on the opposite side of channel-layer 66-2 than source region 50-2S and drain region 50-2D, and a dielectric region may be formed between and contacting source region 50-2S and drain region 50-2D.

In accordance with some embodiments, pass-gate transistor PG2 is oriented upside down than pass-gate transistor PG1, as shown in FIG. 9A. In accordance with alternative embodiments, pass-gate transistor PG2 may be oriented in the same direction as that of pass-gate transistor PG1. The respective structure is shown in FIG. 9B. Accordingly, pass-gate transistor PG2 may have channel layer 62-2 overlying gate 66-2, which may be formed of or comprise a metal oxide. Making pass-gate transistor PG2 to have a same structure as, or a different structure than, pass-gate transistor PG1, and/or oriented a same orientation as, or a different orientation than, pass-gate transistor PG1 may improve the flexibility and the performance of SRAM cell 100.

In accordance with some embodiments, the formation of SRAM cell 100 may include starting the formation of CFETs 10-1 and 10-2 from a wafer. After the formation of CFETs 10-1 and 10-2, pass-gate transistor PG1 may be formed, and the metal lines vias, dielectric layers, metal pads, solder regions (or metal pads) overlying pass-gate transistor PG1 may be formed. The wafer is then flipped, and pass-gate transistor PG2 is formed.

In FIG. 9A, common source region 36-CSU in electrically insulated from common source region 36-CSL by dielectric isolation layer 44. Common source region 36-CSU is overlying and electrically connected to source/drain contact plugs 40U. Common source region 36-CSL is underlying and electrically connected to source/drain contact plugs 40L.

The embodiments of the present disclosure have some advantageous features. By adopting CFETs to form SRAM cells, the footprint of the SRAM cells may be reduced. Since the pass-gate transistors are not paired with any other transistors having opposite types than the pass-gate transistors, the pass-gate transistors cannot take the advantageous of the paired structure of CFETs, and thus the benefit of reducing footprint cannot be obtained fully. In accordance with the embodiments of the present disclosure, the pass-gate transistors are formed overlapping and/or overlapped by the CFETs and occupy the same footprint as the CFETs. The chip usage is thus reduced.

In accordance with some embodiments of the present disclosure, a structure comprises a SRAM cell comprising a first complementary field-effect transistor comprising a first pull-up transistor; and a first pull-down transistor electrically connected to the first pull-up transistor at a first storage node; a second complementary field-effect transistor electrically connecting to the first complementary field-effect transistor and comprising a second pull-up transistor; and a second pull-down transistor electrically connected to the second pull-up transistor at a second storage node; and a first pass-gate transistor overlying the first complementary field-effect transistor and the second complementary field-effect transistor.

In an embodiment, the first pass-gate transistor is directly overlying and overlapping the first complementary field-effect transistor and the second complementary field-effect transistor. In an embodiment, the first pass-gate transistor is directly overlying a first portion of the first complementary field-effect transistor and a second portion of the second complementary field-effect transistor. In an embodiment, the SRAM cell is in a same chip area as a total chip area of the first complementary field-effect transistor and the second complementary field-effect transistor.

In an embodiment, the structure further comprises a second pass-gate transistor underlying the first complementary field-effect transistor and the second complementary field-effect transistor. In an embodiment, the first pass-gate transistor comprises a channel layer comprising a metal oxide. In an embodiment, the first pass-gate transistor comprises InGaZnO. In an embodiment, in a top view of the structure, the first complementary field-effect transistor is elongated and has a first lengthwise direction, and the first pass-gate transistor is elongated and has a second lengthwise direction perpendicular to the first lengthwise direction.

In an embodiment, in a cross-sectional view of the SRAM cell that passes through the first pass-gate transistor, the cross-sectional view comprises a first common source region of the first pull-up transistor and the first pull-up transistor; a second common source region of the second pull-down transistor and the second pull-down transistor; and a dielectric isolation region separating the first common source region from the second common source region. In an embodiment, the first common source region is connected to VDD, and the second common source region is connected to VSS. In an embodiment, the SRAM cell is a six-transistor (6T) SRAM cell.

In accordance with some embodiments of the present disclosure, a structure comprises a SRAM cell comprising a first complementary field-effect transistor occupying a first chip area in a top view of the structure, the first complementary field-effect transistor comprising a first pull-up transistor; and a first pull-down transistor electrically connected to the first pull-up transistor; a second complementary field-effect transistor occupying a second chip area in the top view of the structure, the second complementary field-effect transistor comprising a second pull-up transistor; and a second pull-down transistor electrically connected to the second pull-up transistor; a first pass-gate transistor connected to the first complementary field-effect transistor; and a second pass-gate transistor connected to the second complementary field-effect transistor, wherein in the top view of the structure, the first pass-gate transistor and the second pass-gate transistor are in the first chip area and the second chip area.

In an embodiment, the SRAM cell is a six-transistor SRAM cell. In an embodiment, the first pass-gate transistor is overlying the first complementary field-effect transistor, and the second pass-gate transistor is underlying the first complementary field-effect transistor. In an embodiment, a channel of the first pass-gate transistor comprises a metal oxide. In an embodiment, in the top view of the structure, the first pass-gate transistor and the second pass-gate transistor occupy a same chip area.

In accordance with some embodiments of the present disclosure, a structure comprises a SRAM cell comprising a first complementary field-effect transistor comprising a first pull-up transistor; and a first pull-down transistor electrically connected to the first pull-up transistor; a second complementary field-effect transistor comprising a second pull-up transistor, wherein first source regions and first drain regions of the first pull-up transistor and the second pull-up transistor are aligned to a first straight line in a top view of the structure; and a second pull-down transistor electrically connected to the second pull-up transistor; and a first pass-gate transistor connected to the first complementary field-effect transistor, wherein a second source region and a second drain region of the first pass-gate transistor is aligned to a second straight line in the top view of the structure, and wherein in the top view, the second straight line is perpendicular to the first straight line.

In an embodiment, in the top view, the first pass-gate transistor is in middle of the SRAM cell. In an embodiment, the SRAM cell further comprises a second pass-gate transistor overlapped by the first complementary field-effect transistor and the second complementary field-effect transistor. In an embodiment, the first pass-gate transistor overlaps the second pass-gate transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a static random-access memory (SRAM) cell comprising:
a first complementary field-effect transistor comprising:
a first pull-up transistor; and
a first pull-down transistor electrically connected to the first pull-up transistor at a first storage node;
a second complementary field-effect transistor electrically connecting to the first complementary field-effect transistor and comprising:
a second pull-up transistor; and
a second pull-down transistor electrically connected to the second pull-up transistor at a second storage node; and
a first pass-gate transistor overlying the first complementary field-effect transistor and the second complementary field-effect transistor.

2. The structure of claim 1, wherein the first pass-gate transistor is directly overlying and overlapping the first complementary field-effect transistor and the second complementary field-effect transistor.

3. The structure of claim 2, wherein the first pass-gate transistor is directly overlying a first portion of the first complementary field-effect transistor and a second portion of the second complementary field-effect transistor.

4. The structure of claim 1, wherein the SRAM cell is in a same chip area as a total chip area of the first complementary field-effect transistor and the second complementary field-effect transistor.

5. The structure of claim 1 further comprising a second pass-gate transistor underlying the first complementary field-effect transistor and the second complementary field-effect transistor.

6. The structure of claim 1, wherein the first pass-gate transistor comprises a channel layer comprising a metal oxide.

7. The structure of claim 6, wherein the first pass-gate transistor comprises InGaZnO (IGZO).

8. The structure of claim 1, wherein in a top view of the structure, the first complementary field-effect transistor is elongated and has a first lengthwise direction, and the first pass-gate transistor is elongated and has a second lengthwise direction perpendicular to the first lengthwise direction.

9. The structure of claim 1, wherein in a cross-sectional view of the SRAM cell that passes through the first pass-gate transistor, the cross-sectional view comprises:
a first common source region of the first pull-up transistor and the first pull-up transistor;
a second common source region of the second pull-down transistor and the second pull-down transistor; and
a dielectric isolation region separating the first common source region from the second common source region.

10. The structure of claim 9, wherein the first common source region is connected to VDD, and the second common source region is connected to VSS.

11. The structure of claim 1, wherein the SRAM cell is a six-transistor (6T) SRAM cell.

12. A structure comprising:
a static random-access memory (SRAM) cell comprising:
a first complementary field-effect transistor occupying a first chip area in a top view of the structure, the first complementary field-effect transistor comprising:
a first pull-up transistor; and
a first pull-down transistor electrically connected to the first pull-up transistor;
a second complementary field-effect transistor occupying a second chip area in the top view of the structure, the second complementary field-effect transistor comprising:
a second pull-up transistor; and
a second pull-down transistor electrically connected to the second pull-up transistor;
a first pass-gate transistor connected to the first complementary field-effect transistor; and
a second pass-gate transistor connected to the second complementary field-effect transistor, wherein in the top view of the structure, the first pass-gate transistor and the second pass-gate transistor are in the first chip area and the second chip area.

13. The structure of claim 12, wherein the SRAM cell is a six-transistor SRAM cell.

14. The structure of claim 12, wherein the first pass-gate transistor is overlying the first complementary field-effect transistor, and the second pass-gate transistor is underlying the first complementary field-effect transistor.

15. The structure of claim 12, wherein a channel of the first pass-gate transistor comprises a metal oxide.

16. The structure of claim 12, wherein in the top view of the structure, the first pass-gate transistor and the second pass-gate transistor occupy a same chip area.

17. A structure comprising:
a static random-access memory (SRAM) cell comprising:
a first complementary field-effect transistor comprising:
a first pull-up transistor; and
a first pull-down transistor electrically connected to the first pull-up transistor;
a second complementary field-effect transistor comprising:
a second pull-up transistor, wherein first source regions and first drain regions of the first pull-up transistor and the second pull-up transistor are aligned to a first straight line in a top view of the structure; and
a second pull-down transistor electrically connected to the second pull-up transistor; and
a first pass-gate transistor connected to the first complementary field-effect transistor, wherein a second source region and a second drain region of the first pass-gate transistor is aligned to a second straight line in the top view of the structure, and wherein in the top view, the second straight line is perpendicular to the first straight line.

18. The structure of claim 17, wherein in the top view, the first pass-gate transistor is in middle of the SRAM cell.

19. The structure of claim 17, wherein the SRAM cell further comprises a second pass-gate transistor overlapped by the first complementary field-effect transistor and the second complementary field-effect transistor.

20. The structure of claim 19, wherein the first pass-gate transistor overlaps the second pass-gate transistor.
